(19) United States
(12) Patent Application Publication
(10) Pub. No.: US 2019/0361553 A1
(43) Pub. Date: Nov. 28, 2019

(54) Array Substrate, Display Panel and Display Device

(71) Applicant: Wuhan China Star Optoelectronics Technology Co., Ltd., Wuhan (CN)

(72) Inventors: Weihong Yin, Shenzhen (CN); Ronglei Dai, Shenzhen (CN)

(21) Appl. No.: 16/211,430

(22) Filed: Dec. 6, 2018

Related U.S. Application Data
(63) Continuation of application No. PCT/CN2018/101640, filed on Aug. 22, 2018.

(30) Foreign Application Priority Data
May 28, 2018 (CN) 201810522714.7

(51) Int. Cl. G06F 3/041; H01L 27/12

(52) U.S. Cl. CPC G06F 3/0412; G02F 1/13338; H01L 27/124

(57) ABSTRACT

The embodiments of the present disclosure disclose an array substrate, a display panel and a display device. The array substrate include a substrate body, a plurality of data signal lines, a plurality of touch signal lines, a plurality of first fan-out lines and a plurality of second fan-out lines. The substrate body includes an active area and a non-active area, and the non-active area includes a fan-out area adjacent to the active area. The plurality of first fan-out lines are connected to the plurality of data signal lines in a one-to-one correspondence manner. The plurality of second fan-out lines are connected to the plurality of touch signal lines in a one-to-one correspondence manner. The plurality of first fan-out lines and the plurality of second fan-out lines are made from the same material and located on the same layer.

### CROSS REFERENCE TO RELATED APPLICATIONS

The present application is a continuation-application conversion of International (PCT) Patent Application No. PCT/CN2018/101640 filed on Aug. 22, 2018, which claims foreign priority of Chinese Patent Application No. 201810522714.7, filed on May 28, 2018 in the State Intellectual Property Office of China, the contents of all of which are hereby incorporated by reference.

### TECHNICAL FIELD

This application relates to the technical field of display manufacturing, in particular to an array substrate, a display panel and a display device.

### BACKGROUND

In display panels, lines from drive chip output to an active area are fan-out lines. Existing fan-out lines are generally of a two-layer metal structure which typically adopts an interlaced line arrangement manner by being provided with a first metal layer (M1 layer) located on the same layer with gate lines and a second metal layer (M2 layer) located on the same layer with data lines. Such fan-out lines are provided with two metal layers, and due to the fact that the impendence of metal M1 is large, impedance mismatch in the line area is likely to be caused, consequentially, affecting the display quality.

### SUMMARY

The present disclosure provides an array substrate, a display panel and a display device to avoid impedance mismatch caused by two layers of metal lines.

In order to solve the above-mentioned technical problem, a technical scheme adopted by the present disclosure is: providing an array substrate, comprising a substrate body, a plurality of data signal lines, a plurality of touch signal lines, a plurality of first fan-out lines and a plurality of second fan-out lines; wherein the substrate body comprises an active area and an non-active area, and the non-active layer comprises a fan-out area adjacent to the active area;

the plurality of data signal lines and the plurality of touch signal lines are disposed in the active area;

the plurality of first fan-out lines and the plurality of second fan-out lines are disposed in the fan-out area, wherein the plurality of first fan-out lines are connected to the plurality of data signal lines in a one-to-one correspondence manner, and the plurality of second fan-out lines are connected to the plurality of touch signal lines in a one-to-one correspondence manner;

the plurality of first fan-out lines and the plurality of second fan-out lines are made from a same material and are located on a same layer.

In order to solve the above-mentioned technical problem, another technical scheme adopted by the present disclosure is: providing a display panel, at least comprising an array substrate; wherein the array substrate comprises a substrate body, a plurality of data signal lines, a plurality of touch signal lines, a plurality of first fan-out lines and a plurality of second fan-out lines;

the substrate body comprises an active area and a non-active area, and the non-active area comprises a fan-out area adjacent to the active area;

the plurality of data signal lines and the plurality of touch signal lines are disposed in the active area;

the plurality of first fan-out lines and the plurality of second fan-out lines are disposed in the fan-out area, wherein the plurality of first fan-out lines are connected to the plurality of data signal lines in a one-to-one correspondence manner, and the plurality of second fan-out lines are connected to the plurality of touch signal lines in a one-to-one correspondence manner;

the plurality of first fan-out lines and the plurality of second fan-out lines are made from a same material and are located on a same layer;

wherein the plurality of first fan-out lines, the plurality of second fan-out lines and the plurality of data signal lines are located in a same layer; or

the plurality of first fan-out lines, the plurality of second fan-out lines and the plurality of touch signal lines are located in a same layer;

the plurality of data signal lines and the plurality of touch signal lines are located on different layers, and a plurality of via holes are formed between the layer where the plurality of data signal lines are located and the layer where the plurality of touch signal lines are located;

the plurality of first fan-out lines are connected to the plurality of data signal lines in a one-to-one correspondence manner through the plurality of via holes; or

the plurality of second fan-out lines are connected to the plurality of touch signal lines in a one-to-one correspondence manner through the plurality of via holes.

In order to solve the above-mentioned technical problem, also a technical scheme adopted by the present disclosure is: providing a display device, at least comprising a display panel, and the display panel at least comprising an array substrate; wherein the array substrate comprises a substrate body, a plurality of data signal lines, a plurality of touch signal lines, a plurality of first fan-out lines and a plurality of second fan-out lines;

the substrate body comprises an active area and a non-active area, and the non-active area comprises a fan-out area adjacent to the active area;

the plurality of data signal lines and the plurality of touch signal lines are disposed in the active area;

the plurality of first fan-out lines and the plurality of second fan-out lines are disposed in the fan-out area, wherein the plurality of first fan-out lines are connected to the plurality of data signal lines in a one-to-one correspondence manner, and the plurality of second fan-out lines are connected to the plurality of touch signal lines in a one-to-one correspondence manner;

the plurality of first fan-out lines and the plurality of second fan-out lines are made from a same material and are located on a same layer.

Different from the related art, the array substrate in part of embodiments of this application comprises a substrate body, a plurality of data signal lines, a plurality of touch signal lines, a plurality of first fan-out lines and a plurality of second fan-out lines; the substrate body comprises an active area and a non-active area, the non-active area comprises a fan-out area adjacent to the active area, and the plurality of data signal lines and the plurality of touch signal lines are disposed in the active area; the plurality of first fan-out lines and the plurality of second fan-out areas are disposed in the fan-out area, wherein the plurality of first fan-out lines are connected to the plurality of data signal lines in a one-to-one correspondence manner, and the plurality of second fan-out lines are connected to the plurality of touch signal lines in a one-to-one correspondence manner; and the plurality of first fan-out lines and the plurality of second fan-out lines are made from the same material and are located on the same layer. As the plurality of first fan-out lines and the plurality of second fan-out lines in the array substrate are made from the same material, so that impedance mismatch is avoided, and the display quality is improved; and the plurality of first fan-out lines and the plurality of second fan-out lines are located on the same layer, so that the manufacturing process is shortened, and the procedure is simplified.

### BRIEF DESCRIPTION OF THE DRAWINGS

FIG. 1 is a planar schematic view of a first embodiment of an array substrate of this application.

FIG. 2 is a cross-sectional schematic view of an active area AA in FIG. 1 along a gate line extension direction.

FIG. 3 is a cross-sectional schematic view of a fan-out area FN in FIG. 1 along BB.

FIG. 4 is a connection layout diagram of data signal lines, touch signal lines, first fan-out lines, second fan-out lines and a drive chip in the first embodiment of the array substrate of this application.

FIG. 5 is a layout diagram for connecting the data signal lines to first fan-out lines through metal converters in the first embodiment of the array substrate of this application.

FIG. 6 is a cross-sectional schematic view of the array substrate along the gate line extension direction in a second embodiment of this application.

FIG. 7 is a layout diagram for connecting the data signal lines to the first fan-out lines through metal converters in the second embodiment of the array substrate of this application.

FIG. 8 is a schematic diagram of one embodiment of a display panel of this application.

FIG. 9 is a schematic diagram of one embodiment of a display device of this application.

### DETAILED DESCRIPTION

A clear and complete description of the technical solutions provided by embodiments of this application is given below with reference to the accompanying drawings. Apparently, the embodiments described below are only certain illustrative ones, and do not include all possible embodiments of this application. All other embodiments obtained by those ordinarily skilled in this field based on these illustrative embodiments without creative labor should fall within the protection scope of this application.

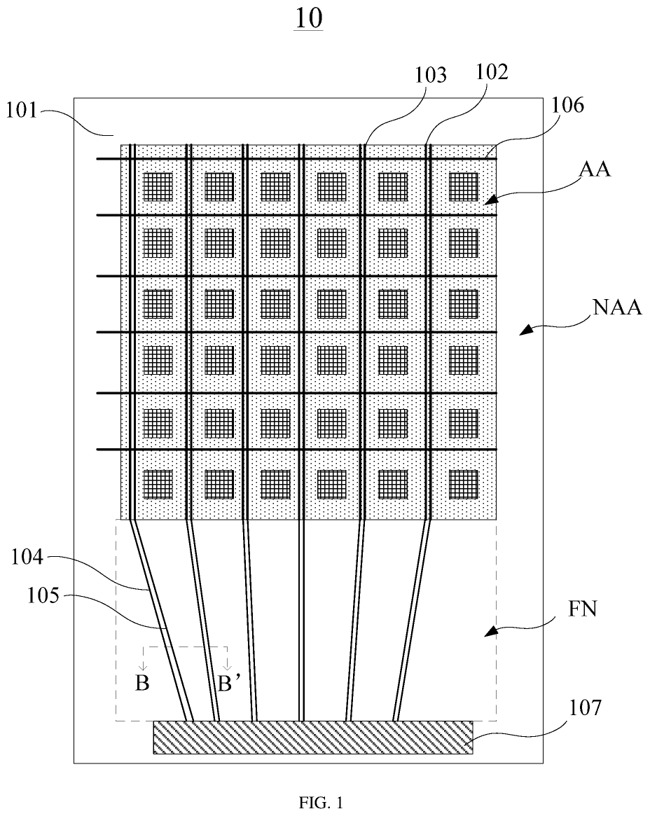

As shown in FIG. 1, in the first embodiment of an array substrate of this application, the array substrate 10 may include a substrate body 101, a plurality of data signal lines 102, a plurality of touch signal lines 103, a plurality of first fan-out lines 104 and a plurality of second fan-out lines 105.

The substrate body 101 may include an active area AA and a non-active area NAA, and the non-active area NAA may include a fan-out area FN adjacent to the active area AA.

The plurality of data signal lines 102 and the plurality of touch signal lines 103 may be disposed in the active area AA, and the plurality of first fan-out lines 104 and the plurality of second fan-out lines 105 may be disposed in the fan-out area FN, wherein the plurality of first fan-out lines 104 may be connected to the plurality of data signal lines 102 in a one-to-one correspondence manner, and the plurality of second fan-out lines 105 may be connected to the plurality of touch signal lines 103 in a one-to-one correspondence manner; and the plurality of first fan-out lines 104 and the plurality of second fan-out lines 105 may be made from the same material and may be located on the same layer.

In one embodiment, the plurality of first fan-out lines 104 and the plurality of second fan-out lines 105 may be made from a small-impedance metallic material (such as M2). For instance, aluminum, copper, gold and the like, so that the line impedance is small. Compared with the related art, the line arrangement load of the plurality of data signal lines or the plurality of touch signal lines in the fan-out area FN is small, thus, improving the display quality. Definitely, the plurality of first fan-out lines 104 and the plurality of second fan-out lines 105 may also be made from other materials such as ITO, and this application has not specific limitation in this regard.

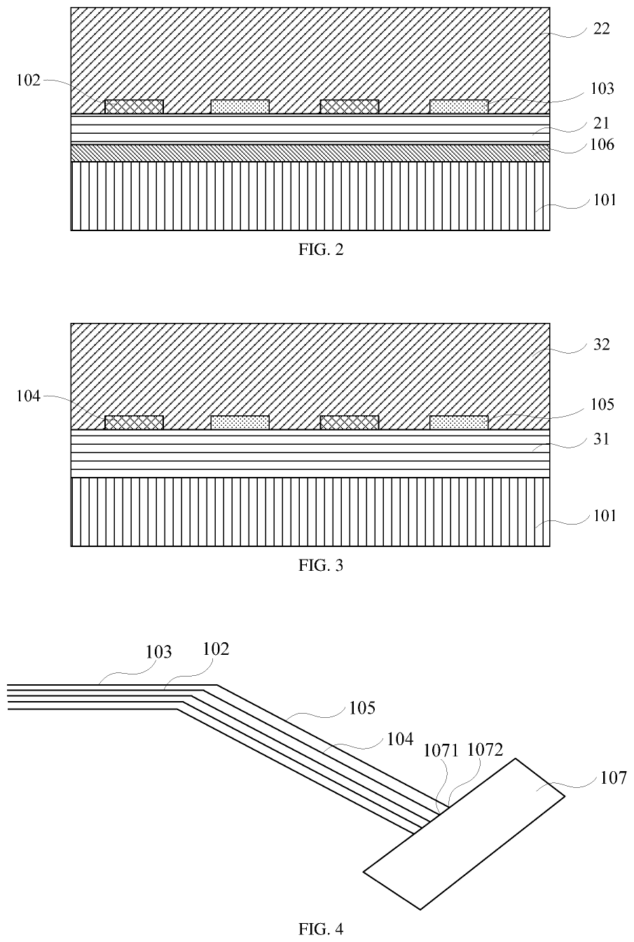

Particularly, as shown in FIG. 2, in one application case, the plurality of gate signal lines 106 may be disposed intersecting with the plurality of data signal lines 102 in the active area AA, and the plurality of touch signal lines 103 and the plurality of data signal lines 102 may be located on the same layer. As shown in FIG. 2, the plurality of gate signal lines 106 may be disposed on a surface of the substrate body 101, a first insulation layer 21 may be disposed on surfaces, away from the substrate body 101, of the plurality of gate signal lines 106, the plurality of touch signal lines 103 and the plurality of data signal lines 102 may be disposed on a surface, away from the plurality of gate signal lines 106, of the first insulation layer 21, and the plurality of touch signal lines 103 and the plurality of data signal lines 102 may be alternately arrayed. Definitely, in other application cases, the plurality of touch signal lines 103 and the plurality of data signal lines 102 may be arrayed according to actual requirements, for instance, two data signal lines 102, one touch signal line 103 and two data signal lines 102 are alternately arrayed.

In the non-active area NAA, each first fan-out line 104 may be connected to one corresponding data signal line 102, and each second fan-out line 105 may be connected to one corresponding touch signal line 103. Wherein the corresponding relation between the first fan-out line 104 and the data signal line 102 and the corresponding relation between the second fan-out line 105 and the touch signal line 103 may be set according to the positions of pins of a drive chip 107, and this application has no specific limitation in this regard. The first fan-out line 104 and the second fan-out line 105 may be disposed on the same layer. For instance, in the non-active area NAA, a second insulation layer 31 may be formed on the surface of the substrate body 101 and may be located on the same layer with the first insulation layer 21 in the active area AA, the first fan-out line 104 and the second fan-out line 105 may be disposed on a surface, away from the substrate body 101, of the second insulation layer 31. A third insulation layer 32 may be disposed on surfaces, away from the first fan-out line 104, the second fan-out line 105 and the second insulation layer 31, thus, the first fan-out line 104, the second fan-out line 105 and the second insulation layer 31 may be covered with the third insulation layer 32 (or planarization layer), as shown in FIG. 3.

Optionally, as shown in FIG. 1 and FIG. 4, the array substrate 10 may further include a drive chip 107 disposed in the non-active area NAA. The drive chip 107 may include a plurality of first pins 1071 and a plurality of second pins 1072. An end of the first fan-out line 104 may be connected to the corresponding data signal line 102 and another end of the first fan-out line 104 may be connected to the corresponding first pin 1071 of the drive chip 107. An end of the second fan-out line 105 may be connected to the corresponding touch signal line 103 and another end of the second fan-out line 105 may be connected to the corresponding second pin 1072 of the drive chip 107. In one embodiment, the first fan-out line 104 and the second fan-out line 105 extend along the same direction, for instance, the first fan-out line 104 is parallel to the second fan-out line 105, as shown in FIG. 4. The shape, extension direction and the like of the first fan-out line 104 and the second fan-out line 105 may be set according to actual requirements, and this application has no specific limitation in this regard.

Optionally, the drive chip 107 may be an Interlace IC. The Interlace IC 107 may include a plurality of first pins 1071 and a plurality of second pins 1072, wherein the plurality of first pins 1071 and the plurality of second pins 1072 may be alternately arrayed. Definitely, the drive chip 107 may also be chips of other types in other embodiments, and this application has no specific limitation in this regard.

Furthermore, as shown in FIG. 4, in the above embodiments, the plurality of first pins 1071 and the plurality of second pins 1072 of the drive chip 107 may be arrayed in one-to-one correspondence with the plurality of first fan-out lines 104 and the plurality of second fan-out lines 105. Namely, as shown in FIG. 4, the plurality of first fan-out lines 104 and the plurality of second fan-out lines 105 extend in parallel and are connected to the corresponding plurality of first pins 1071 and the corresponding plurality of second pins 1072 without line jumping/perforating, so that the plurality of first pins 1071 may input a drive signal to the corresponding plurality of data signal lines 102 via the plurality of first fan-out lines 104, and the plurality of second pins 1072 may transmit a drive signal to the corresponding plurality of touch signal lines 103 via the plurality of second fan-out lines 105. As the plurality of data signal lines 102 and the plurality of touch signal lines 103 are disposed on the same layer, if the plurality of data signal lines 102 and the plurality of touch signal lines 103 are arrayed in one-to-one correspondence with the plurality of first pins 1071 and the plurality of second pins 1072 of the drive chip 107, the plurality of first fan-out lines 104 and the plurality of second fan-out lines 105 may be directly connected to the corresponding plurality of data signal lines 102 and the plurality of touch signal lines 103 and then extend in one direction to be connected to the corresponding plurality of first pins 1071 and the corresponding plurality of second pins 1072 without line jumping/perforating .

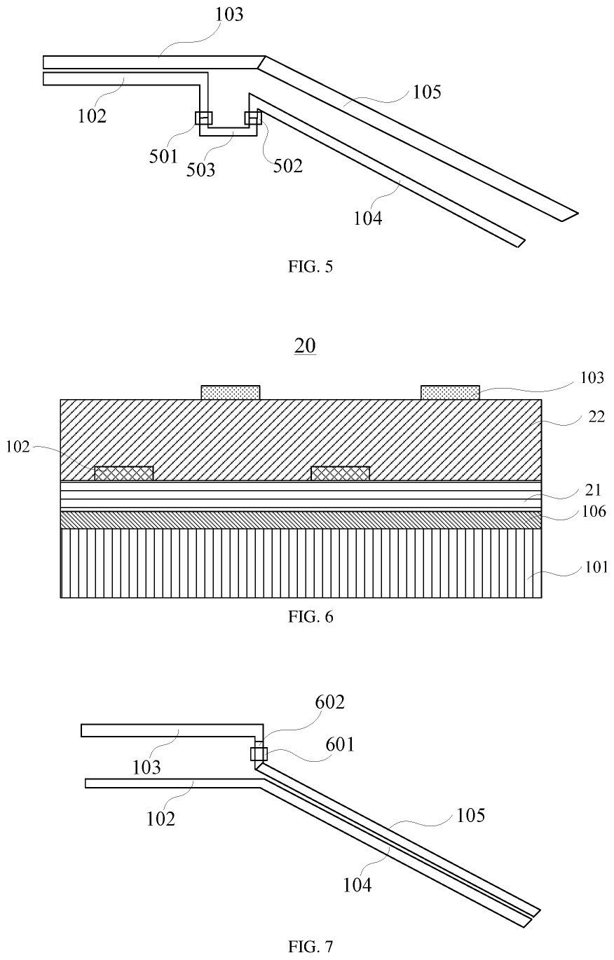

Definitely, in other embodiments, if the plurality of first pins 1071 and the plurality of second pins 1072 of the drive chip 107 are not arrayed in one-to-one correspondence with the plurality of data signal lines 102 and the plurality of touch signal lines 103, the plurality of first fan-out lines 104 and the plurality of second fan-out lines 105 may be arrayed in such a manner that the plurality of data signal lines 102 are connected to the corresponding plurality of first pins 1071 through the plurality of first fan-out lines 104 and the plurality of touch signal lines 103 are connected to the plurality of second pins 1072 through the plurality of second fan-out lines 105. Wherein the arrangement sequence of the plurality of first fan-out lines 104 and/or the plurality of second fan-out lines 105 may be adjusted through metal converters, so that the plurality of data signal lines 102 are connected to the corresponding plurality of first fan-out lines 104, and the plurality of touch signal lines 103 are connected to the corresponding plurality of second fan-out lines 105. Specifically, as shown in FIG. 5, with one of the data signal lines 102 as an example, a first through hole 501 may be formed in a corresponding position of an end, to be connected to the corresponding first fan-out line 104, of the data signal line 102, a second through hole 502 may be formed in a corresponding position of an end, to be connected with the data signal line 102, of the corresponding first fan-out line 104, one end of a metal converter 503 may be connected to the data signal line 102 via the first through hole 501, the other end of the metal converter 503 may be connected to the corresponding first fan-out line 104 via the second through hole 502, and thus, the first fan-out line 104 and the corresponding data signal line 102 may be connected through the metal converter 503. The metal converter 503 may be made from a metal (such as M1) different from the first fan-out line 104. The touch signal line 103 may also be corresponding connected to the second fan-out line 105 through a similar method (namely through metal converters), and the metal converters used for connecting the touch signal line 103 to the corresponding second fan-out line 105 may be made from the same metal (such as M2) with the second fan-out line 105.

In this embodiment, the plurality of data signal lines 102, the plurality of touch signal lines 103, the plurality of first fan-out lines 104 and the plurality of second fan-out lines 105 may be disposed on the same layer, so that in the process of manufacturing the array substrate 10, the plurality of data signal lines 102, the plurality of touch signal lines 103, the plurality of first fan-out lines 104 and the plurality of second fan-out lines 105 may be manufactured at the same time and may be made on the same metal layer, and thus, the manufacturing process is shortened, and the cost is reduced.

Definitely, in other embodiments, the plurality of data signal lines and the plurality of touch signal lines may also be located on different layers.

Specifically, as shown in FIG. 6, in the second embodiment of the array substrate of this application, the array substrate 20 is similar to the array substrate 10, the similarities will no longer be described herein, and the difference lies in that the plurality of data signal lines 102 and the plurality of touch signal lines 103 are located on different layers.

As shown in FIG. 3, the plurality of first fan-out lines 104 and the plurality of second fan-out lines 105 are located on the same layer.

Optionally, the plurality of first fan-out lines 104, the plurality of second fan-out lines 105 and the plurality of data signal lines 102/touch signal lines 103 are located on the same layer.

Specifically, in one application case, as shown in FIG. 7, as the plurality of data signal lines 102 and the plurality of touch signal lines 103 are located on different layers, if the plurality of first fan-out lines 104 and the plurality of second fan-out lines 105 are disposed on the layer where the data signal lines 102 are located. A plurality of via holes 601 may be formed between the layer where the plurality of data signal lines 102 are located and the layer where the plurality of touch signal lines 103 are located, the plurality of first fan-out lines 104 may be directly connected to the corresponding plurality of data signal lines 102, the plurality of second fan-out lines 105 may be connected to the plurality of touch signal lines 103 in a one-to-one correspondence manner through the plurality of via holes 601, and then the plurality of touch signal lines 103 may be directly connected to the corresponding plurality of pins of the drive chip through the plurality of second fan-out lines 105 without line jumping/line conversion, and thus, the line arrangement difficulty is lowered; and as the lines 102 in the fan-out area are disposed on the layer where the plurality of data signal lines are located, compared with the existing two-layer structure, the distance between the plurality of second fan-out lines 105 and a common electrode (COM) is increased, and accordingly, the parasitic capacitance between the plurality of second fan-out lines 105 and COM is reduced.

Wherein a plurality of metal converters 602 may be disposed in the plurality of via holes 601 and may be located between the layer where the plurality of data signal lines 102 are located and the layer where the plurality of touch signal lines 103 are located in a spanning manner through the plurality of via holes 601. An end of the metal converter 602 may be connected to the corresponding touch signal line 103 and another end of the metal converter 602 may be connected to the corresponding second fan-out line 105. Wherein the metal converter 602 and the second fan-out line 105 may be made from the same material (such as M1) and may also be made from different materials (for instance, the second fan-out line 105 is made from M1, while the metal converter 602 is made from M2). In other application cases, the plurality of first fan-out lines 104 and the plurality of second fan-out lines 105 may also be disposed on the layer where the plurality of touch signal lines 103 are located, and the specific implementation is similar to the above process and is no longer described herein.

Definitely, in other embodiments, the plurality of first fan-out lines 104 and the plurality of second fan-out lines 105 may also be disposed on other layers different from the layer where the plurality of data signal lines 102 and the layer where the plurality of touch signal lines 103 are located according to the actual load condition of a display panel. The plurality of data signal lines 102 and the plurality of touch signal lines 103 may be connected to the corresponding plurality of first fan-out lines 104 and the corresponding plurality of second fan-out lines 105 through the plurality of metal converters, and the specific implementation is similar to the above process and is no longer described herein.

According to the array substrate in this embodiment, the first fan-out lines and the second fan-out lines are made from the same material, so that impedance mismatch is avoided, and the display quality is improved; and the first fan-out lines and the second fan-out lines are located on the same layer, so that the manufacturing process is shortened, and the procedure is simplified.

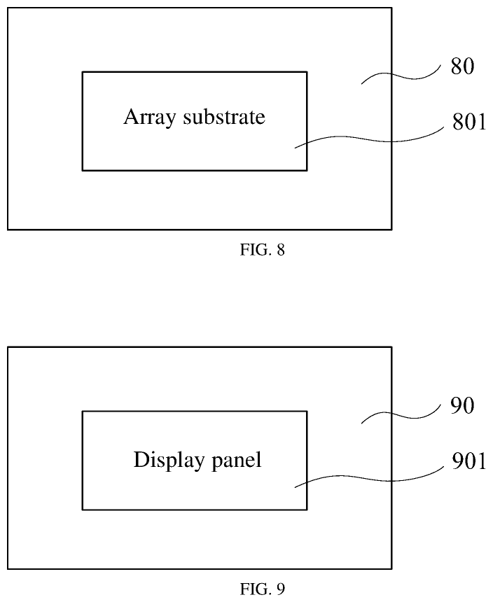

As shown in FIG. 8, in one embodiment of a display panel of this application, the display panel 80 may at least include an array substrate 801. Please refer to the structure of the first or second embodiment of the array substrate of this application for the array substrate 801, and a repeated description will no longer be given herein.

The display panel 80 may further include a color filter substrate, a liquid crystal layer and the like according to the specific type of the display panel, and this application has no specific limitation in this regard.

The plurality of first fan-out lines and the plurality of second fan-out lines in the array substrate of the display panel in this embodiment are made from the same material, so that impedance mismatch is avoided, and the display quality is improved; and the plurality of first fan-out lines and the plurality of second fan-out lines are located on the same layer, so that the manufacturing process is shortened, and the procedure is simplified.

As shown in FIG. 9, in one embodiment of a display device of this application, the display device 90 may at least include a display panel 901. Please refer to the structure of the display panel in the above embodiment of this application for the display panel 901, and a repeated description will no longer be given herein.

According to the display device 90 in this embodiment, the plurality of first fan-out lines and the plurality of second fan-out lines in the array substrate of the display panel 901 are made from the same material, so that impedance mismatch is avoided, and the display quality is improved; and the plurality of first fan-out lines and the plurality of second fan-out lines are located on the same layer, so that the manufacturing process is shortened, and the procedure is simplified.

The above description is only used for explaining several embodiments of this application and is not intended to limit the patent scope of this application. All equivalent structures or equivalent flow transformations based on the contents of the specification and accompanying drawings of this application, or direct or indirect applications to other relevant technical fields should fall within the patent protection scope of this application.

What is claimed is:

1. A display panel, at least comprising an array substrate; wherein the array substrate comprises a substrate body, a plurality of data signal lines, a plurality of touch signal lines, a plurality of first fan-out lines and a plurality of second fan-out lines;
the substrate body comprises an active area and a non-active area, and the non-active area comprises a fan-out area adjacent to the active area;
the plurality of data signal lines and the plurality of touch signal lines are disposed in the active area;
the plurality of first fan-out lines and the plurality of second fan-out lines are disposed in the fan-out area, wherein the plurality of first fan-out lines are connected to the plurality of data signal lines in a one-to-one correspondence manner, and the plurality of second fan-out lines are connected to the plurality of touch signal lines in a one-to-one correspondence manner;
the plurality of first fan-out lines and the plurality of second fan-out lines are made from a same material and are located on a same layer;
wherein the plurality of first fan-out lines, the plurality of second fan-out lines and the plurality of data signal lines are located in a same layer; or
the plurality of first fan-out lines, the plurality of second fan-out lines and the plurality of touch signal lines are located in a same layer;
the plurality of data signal lines and the plurality of touch signal lines are located on different layers, and a plurality of via holes are formed between the layer where the plurality of data signal lines are located and the layer where the plurality of touch signal lines are located;
the plurality of first fan-out lines are connected to the plurality of data signal lines in a one-to-one correspondence manner through the plurality of via holes; or
the plurality of second fan-out lines are connected to the plurality of touch signal lines in a one-to-one correspondence manner through the plurality of via holes.

2. The display panel according to claim 1, wherein the array substrate further comprises a plurality of metal converters, which are disposed between the layer where the plurality of data signal lines are located and the layer where the plurality of touch signal lines are located in a spanning manner through the plurality of via holes, and an end of the metal converter is connected to the data signal line, another end of the metal converter is connected to the corresponding first fan-out line; or
an end of the metal converter is connected to the touch signal line, another end of the metal converter is connected to the corresponding second fan-out line.

3. The display panel according to claim 1, wherein the array substrate further comprises a drive chip, which is disposed in the non-active area and comprises a plurality of first pins and a plurality of second pins; an end of the first fan-out line is connected to the data signal line and another end connected to the corresponding first pin of the drive chip; an end of the second fan-out line is connected to the touch signal line and another end is connected to the corresponding second pin of the drive chip.

4. The display panel according to claim 1, wherein the drive chip is an Interlace integrated chip which comprises a plurality of first pins and a plurality of second pins, and the plurality of first pins and the plurality of second pins are alternately arrayed.

5. An array substrate, comprising a substrate body, a plurality of data signal lines, a plurality of touch signal lines, a plurality of first fan-out lines and a plurality of second fan-out lines; wherein the substrate body comprises an active area and an non-active area, and the non-active layer comprises a fan-out area adjacent to the active area;
the plurality of data signal lines and the plurality of touch signal lines are disposed in the active area;
the plurality of first fan-out lines and the plurality of second fan-out lines are disposed in the fan-out area, wherein the plurality of first fan-out lines are connected to the plurality of data signal lines in a one-to-one correspondence manner, and the plurality of second fan-out lines are connected to the plurality of touch signal lines in a one-to-one correspondence manner;
the plurality of first fan-out lines and the plurality of second fan-out lines are made from a same material and are located on a same layer.

6. The array substrate according to claim 5, wherein the plurality of first fan-out lines, the plurality of second fan-out lines and the plurality of data signal lines are located in a same layer; or
the plurality of first fan-out lines, the plurality of second fan-out lines and the plurality of touch signal lines are located in a same layer.

7. The array substrate according to claim 5, wherein the plurality of data signal lines and the plurality of touch signal lines are located on different layers, and a plurality of via holes are formed between the layer where the plurality of data signal lines are located and the layer where the plurality of touch signal lines are located;
the plurality of first fan-out lines are connected to the plurality of data signal lines in a one-to-one correspondence manner through the plurality of via holes; or
the plurality of second fan-out lines are connected to the plurality of touch signal lines in a one-to-one correspondence manner through the plurality of via holes.

8. The array substrate according to claim 7, wherein the array substrate further comprises a plurality of metal converters which are disposed between the layer where the plurality of data signal lines are located and the layer where the plurality of touch signal lines are located in a spanning manner through the plurality of via holes, and an end of the metal converter is connected to the data signal line, another end of the metal converter is connected to the corresponding first fan-out line; or
an end of the metal converter is connected to the touch signal line, another end of the metal converter is connected to the corresponding second fan-out line.

9. The array substrate according to claim 5, wherein the array substrate further comprises a drive chip, which is disposed in the non-active area and comprises a plurality of first pins and a plurality of second pins;
an end of the first fan-out line is connected to the data signal line and another end connected to the corresponding first pin of the drive chip; an end of the second fan-out line is connected to the touch signal line and another end is connected to the corresponding second pin of the drive chip.

10. The array substrate according to claim 9, wherein the drive chip is an Interlace integrated chip which comprises a plurality of first pins and a plurality of second pins, and the plurality of first pins and the plurality of second pins are alternately arrayed.

11. The array substrate according to claim 5, wherein the plurality of first fan-out lines and the plurality of second fan-out lines are made from metallic materials.

12. The array substrate according to claim 5, wherein the plurality of first fan-out lines and the plurality of second fan-out lines extend along a same direction.

13. A display device, at least comprising a display panel, and the display panel at least comprising an array substrate; wherein the array substrate comprises a substrate body, a plurality of data signal lines, a plurality of touch signal lines, a plurality of first fan-out lines and a plurality of second fan-out lines;
the substrate body comprises an active area and a non-active area, and the non-active area comprises a fan-out area adjacent to the active area;
the plurality of data signal lines and the plurality of touch signal lines are disposed in the active area;
the plurality of first fan-out lines and the plurality of second fan-out lines are disposed in the fan-out area, wherein the plurality of first fan-out lines are connected to the plurality of data signal lines in a one-to-one correspondence manner, and the plurality of second fan-out lines are connected to the plurality of touch signal lines in a one-to-one correspondence manner;
the plurality of first fan-out lines and the plurality of second fan-out lines are made from a same material and are located on a same layer.

14. The display device according to claim 13, wherein the plurality of first fan-out lines, the plurality of second fan-out lines and the plurality of data signal lines are located in a same layer; or
the plurality of first fan-out lines, the plurality of second fan-out lines and the plurality of touch signal lines are located in a same layer.

15. The display device according to claim 13, wherein the plurality of data signal lines and the plurality of touch signal lines are located on different layers, and a plurality of via holes are formed between the layer where the plurality of data signal lines are located and the layer where the plurality of touch signal lines are located;
the plurality of first fan-out lines are connected to the plurality of data signal lines in a one-to-one correspondence manner through the plurality of via holes; or
the plurality of second fan-out lines are connected to the plurality of touch signal lines in a one-to-one correspondence manner through the plurality of via holes.

16. The display device according to claim 15, wherein the array substrate further comprises a plurality of metal converters which are disposed between the layer where the plurality of data signal lines are located and the layer where the plurality of touch signal lines are located in a spanning manner through the plurality of via holes, and an end of the metal converter is connected to the data signal line, another end of the metal converter is connected to the corresponding first fan-out line; or
an end of the metal converter is connected to the touch signal line, another end of the metal converter is connected to the corresponding second fan-out line.

17. The display device according to claim 13, wherein the array substrate further comprises a drive chip, which is disposed in the non-active area and comprises a plurality of first pins and a plurality of second pins;
an end of the first fan-out line is connected to the data signal line and another end connected to the corresponding first pin of the drive chip; an end of the second fan-out line is connected to the touch signal line and another end is connected to the corresponding second pin of the drive chip.

18. The display device according to claim 17, wherein the drive chip is an Interlace integrated chip which comprises a plurality of first pins and a plurality of second pins, and the plurality of first pins and the plurality of second pins are alternately arrayed.

19. The display device according to claim 13, wherein the plurality of first fan-out lines and the plurality of second fan-out lines are made from metallic materials.

20. The display device according to claim 13, wherein the plurality of first fan-out lines and the plurality of second fan-out lines extend along a same direction.
